(19) United States
(12) Patent Application Publication
(10) Pub. No.: US 2012/0270358 A1
(43) Pub. Date: Oct. 25, 2012

(54) Method for Fabrication of an Array of Chip-Sized Photovoltaic Cells for a Monolithic Low Concentration Photovoltaic Panel Based on Crossed Compound Parabolic Concentrators

(75) Inventors: Zohar Haviv, Har-Adar (IL); Mauricio De-La-Vega, Modi'in (IL)

(73) Assignee: Impel Microchip Ltd., Har-Adar (IL)

(21) Appl. No.: 13/503,889

(22) PCT Filed: Oct. 21, 2010
(86) PCT No.: PCT/IL2010/000870

§ 371 Date: Jul. 10, 2012

Related U.S. Application Data
(60) Provisional application No. 61/254,891, filed on Oct. 26, 2009.

(51) Int. Cl. H01L 31/18

(52) U.S. Cl. 438/68; 257/E31.11

(57) ABSTRACT

Method for determining the dimensions of a plurality of chip-size photovoltaic cells diced out of a photovoltaic wafer, the method includes the procedures of determining the field of view angle of a plurality of crossed compound parabolic concentrators of an optical layer, determining the index of refraction of the material forming the optical layer, determining the dimensions of the optical entry aperture and the optical exit aperture of the crossed compound parabolic concentrators, as well as the distance separating the optical entry apertures of adjacent ones of the crossed compound parabolic concentrators, determining a dicing width for dicing the photovoltaic wafer into the plurality of chip-size photovoltaic cells, and determining the dimensions of the plurality of chip-size photovoltaic cells according to the dimensions of the optical entry aperture of the plurality of crossed compound parabolic concentrators, the distance separating the optical entry apertures of adjacent ones of the crossed compound parabolic concentrators, the index of refraction of the optical layer, the field of view angle of the plurality of crossed compound parabolic concentrators and according to the dicing width.

### FIELD OF THE DISCLOSED TECHNIQUE

The disclosed technique relates to concentrating photovoltaic panels in general, and to methods and systems for fabrication of an array of chip-sized photovoltaic cells in particular.

### BACKGROUND OF THE DISCLOSED TECHNIQUE

In flat panel photovoltaic technologies (e.g., based on mono-crystalline silicon wafers, poly-crystalline silicon wafers, multi-junction cells and tandem cells), the cost of the photovoltaic material dictates a large portion of the total panel cost. For example, in case of mono-crystalline based solar panels, the cost of silicon wafers carries approximately 65% of the total panel cost.

Concentrating photovoltaic technologies are employed in order to reduce the photovoltaic material content of the solar panel, thereby, reducing its cost. Expensive photovoltaic materials are replaced by relatively cheap lenses and optical concentrators. The larger the optical concentration value of the system (i.e., the amount of light radiation energy focused onto a specific surface area), the lower will be the total active photovoltaic area of the system.

Reference is now made to FIG. 1, which is a schematic illustration of a concentrating photovoltaic device, generally referenced 10, constructed and operative as known in the art. Concentrating photovoltaic device 10 includes a photovoltaic cell 12, a substrate 14, a plurality of interconnects 16, a plurality of wires 18 and a lens 20. Photovoltaic cell 12 is positioned on top of substrate 14, approximately in the center thereof. Photovoltaic cell 12 can be any photovoltaic cell known in the art, such as a mono-crystalline silicon cell, a poly-crystalline silicon cell, a multi-junction cell, or a tandem cell. Photovoltaic cell 12 converts light radiation into electrical current. Substrate 14 functions as a structural base, and as a heat sink, for photovoltaic cell 12.

Wires 18 transfer the generated electrical current from photovoltaic cell 12 to interconnects 16. Lens 20 is a concentrating lens, which concentrates light radiation toward photovoltaic cell 12. For example, lens 20 concentrates each of parallel beams 22A, 24A and 26A toward photovoltaic cell 12. Each of concentrated beams 22B, 24B and 26B corresponds to each of un-concentrated parallel beams 22A, 24A and 26A. The distance of between lens 20 and photovoltaic cell 12 is determined by the value of a depth of focus of concentrating photovoltaic device 10. The value of the depth of focus of concentrating photovoltaic device 10 is related to the concentration power and the design of lens 20, and to the size of photovoltaic cell 12.

In most concentrating photovoltaic panels that include an array of concentrating photovoltaic devices (e.g., photovoltaic device 10), each photovoltaic cell is assembled and interconnected individually. At high optical concentration values, the total active photovoltaic area required by the system is small, and hence small sized photovoltaic cells are employed. For example, in high optical concentration applications, photovoltaic cells with areas down to 4 millimeters square are employed.

A view angle is the angle of incoming light beams, which an optical element can receive (i.e., field of view). Low concentration photovoltaic devices operate at high view angles (i.e., large field of view), and thus do not require mechanical sun tracking devices. Low concentration photovoltaic devices obtain optical concentrations of up to a factor of ten.

Table 1 herein below, describes the number of photovoltaic cells, required for covering a 1m×1m panel, as a function of photovoltaic cell size and of concentration factor (i.e., table 1 relates to the number of photovoltaic cells as known in the art). From Table 1 it is apparent that the number of photovoltaic cells required for covering a 1m×1m panel, increases with decreasing die size and increases with decreasing concentration factor.

TABLE 1
The number of photovoltaic cells required for covering a 1 m × 1 m
panel (cell size in millimeters Vs. concentration factor)

| | ×2 | ×10 | ×100 | ×1000 |
|---|---|---|---|---|
| 10 × 10 | 5000 | 1000 | 100 | 10 |
| 5 × 5 | 20,000 | 4000 | 400 | 40 |
| 2 × 2 | 125,000 | 25,000 | 2500 | 250 |
| 1 × 1 | 500,000 | 100,000 | 10,000 | 1000 |
| 0.5 × 0.5 | 2,000,000 | 400,000 | 40,000 | 4000 |
| 0.1 × 0.1 | 50,000,000 | 10,000,000 | 1,000,000 | 100,000 |

In prior art systems, at low optical concentration values, the total active photovoltaic area required by the system is large, and hence small sized photovoltaic cells are rarely employed.

### SUMMARY OF THE DISCLOSED TECHNIQUE

It is an object of the disclosed technique to provide a novel method and system for fabrication of an array of chip sized of photovoltaic cells for a monolithic low concentration photovoltaic panel based on crossed compound parabolic concentrators, which overcomes the disadvantages of the prior art.

In accordance with the disclosed technique, there is thus provided a method for determining the dimensions of a plurality of chip-size photovoltaic cells diced out of a photovoltaic wafer. The method includes the procedures of determining the field of view angle of a plurality of crossed compound parabolic concentrators of an optical layer, determining the index of refraction of the material forming the optical layer, determining the dimensions of the optical entry aperture and the optical exit aperture of the crossed compound parabolic concentrators, determining a dicing width for dicing the photovoltaic wafer, and determining the dimensions of the plurality of chip-size photovoltaic cells. The procedure of determining the dimensions of the optical entry aperture and the optical exit aperture of the crossed compound parabolic concentrators, further includes determining the distance separating the optical entry apertures of adjacent ones of the crossed compound parabolic concentrators. The procedure of determining the dimensions of the plurality of chip-size photovoltaic cells is performed according to the dimensions of the optical entry aperture of the plurality of crossed compound parabolic concentrators, the distance separating the optical entry apertures of adjacent ones of the crossed compound parabolic concentrators, the index of refraction of the optical layer, the field of view angle of the plurality of crossed compound parabolic concentrators and according to the dicing width.

In accordance with another aspect of the disclosed technique there is thus provided a method for separating an array of chip-sized photovoltaic cells out of a photovoltaic wafer, and transferring the array onto a support substrate. The method includes the procedures of coupling the photovoltaic wafer with a dicing tape, dicing the photovoltaic wafer for producing at least the array of chip-sized photovoltaic cells, positioning a multi-head vacuum jig above the photovoltaic wafer, and transferring the array of chip-sized photovoltaic cells onto the support substrate. The procedure of positioning a multi-head vacuum jig above the photovoltaic wafer is performed such that each of a plurality of vacuum heads of the vacuum jig being positioned above each of the cells of the array of chip-sized photovoltaic cells.

In accordance with yet another aspect of the disclosed technique there is thus provided a method for separating an array of chip-sized photovoltaic cells out of a photovoltaic wafer, and transferring the array onto a support substrate. The method comprising the procedures of dicing the photovoltaic wafer, aligning a nonstick mask to the top surface of the photovoltaic wafer, aligning an adhesive tape substrate to the top surface of the non stick mask and the photovoltaic wafer, pressing the adhesive tape substrate against the non-stick mask, and transferring the array of chip-sized photovoltaic cells onto the support substrate. The procedure of dicing the photovoltaic wafer is directed at producing at least the array of chip sized photovoltaic cells. The non stick mask includes a plurality of openings. Each of the openings corresponds in dimensions and position to a respective cell of the array of chip sized photovoltaic cells. The procedure of pressing the adhesive tape substrate against the non-stick mask is performed such that the adhesive tape substrate adheres to the array of chip-sized photovoltaic cells through the openings of the non-stick mask.

### BRIEF DESCRIPTION OF THE DRAWINGS

The disclosed technique will be understood and appreciated more fully from the following detailed description taken in conjunction with the drawings in which:

FIG. 1 is a schematic illustration of a concentrating photovoltaic device, constructed and operative as known in the art;

FIG. 2A is a schematic illustration of a top isometric view of a concentrating photovoltaic panel, constructed and operative in accordance with an embodiment of the disclosed technique;

FIG. 2B is a schematic illustration of a bottom isometric view of the photovoltaic concentrating panel of FIG. 2A;

FIG. 3 is a schematic illustration of a cross section view of a concentrating photovoltaic panel, constructed and operative in accordance with another embodiment of the disclosed technique;

FIG. 4 is a schematic illustration of three wafer-size photovoltaic cells, constructed and operative in accordance with a further embodiment of the disclosed technique;

FIG. 5A is a schematic illustration of a bottom view of a portion of an optical layer, including six crossed CPCs, constructed and operative in accordance with another embodiment of the disclosed technique;

FIG. 5B is a schematic illustration of a top view of the portion of the optical layer of FIG. 5A;

FIG. 5C is a schematic illustration of a cross section of a ZX plane of the portion of the optical layer of FIG. 5A;

FIG. 5D is a schematic illustration of a cross section of a ZY plane of the portion of the optical layer of FIG. 5A;

FIG. 6A is a schematic illustration of a portion of a wafer-sized photovoltaic cell, diced into a plurality of chip-sized photovoltaic cells, constructed and operative in accordance with a further embodiment of the disclosed technique;

FIG. 6B is a schematic illustration of a cross section of a ZX plane of the wafer-sized photovoltaic cell of FIG. 6A;

FIG. 6C is a schematic illustration of a cross section of a ZY plane of the wafer-sized photovoltaic cell of FIG. 6A;

FIG. 7 is a schematic illustration of a portion of a wafer-sized photovoltaic cell, diced into a plurality of chip-sized photovoltaic cells, constructed and operative in accordance with another embodiment of the disclosed technique;

FIG. 8 is a schematic illustration of a top view of a chip-size photovoltaic cell, including both a top contact and a bottom contact, constructed and operative in accordance with a further embodiment of the disclosed technique;

FIG. 9 is a schematic illustration of a top view of a portion of a wafer-size photovoltaic cell, after the deposition of a passivation layer, constructed and operative in accordance with another embodiment of the disclosed technique;

FIG. 10 is a block diagram illustration of a method for determining the dimensions of a chip-size photovoltaic cell and the number of arrays of such chip-size photovoltaic cells, operative in accordance with a further embodiment of the disclosed technique;

FIGS. 11A, 11B, 11C, 11D, and 11E, are schematic illustrations of the steps for performing a first method for separating an array of chip-size photovoltaic cells, diced out of a wafer-size photovoltaic panel, and transferring the array onto a support substrate, operative in accordance with another embodiment of the disclosed technique;

FIG. 12A is a bottom view schematic illustration of a multi-head vacuum jig, constructed and operative in accordance with a further embodiment of the disclosed technique;

FIG. 12B is a top view schematic illustration of the multi-head vacuum jig of FIG. 12A;

FIG. 12C is a rear view schematic illustration of the multi-head vacuum jig of FIG. 12A;

FIGS. 13A, 13B and 13C, are schematic illustrations of the steps for performing a second method for separating an array of chip-size photovoltaic cells, diced out of a wafer-size photovoltaic cell, and transferring the array onto a support substrate, operative in accordance with another embodiment of the disclosed technique;

FIG. 14 is a schematic illustration of a UV mask, constructed and operative in accordance with a further embodiment of the disclosed technique; and

FIGS. 15A, 15B, 15C, 15D, 15E and 15F, are schematic illustrations of the steps for performing a third method for separating an array of chip-size photovoltaic cells, diced out of a wafer-size photovoltaic cell, and transferring the array onto a support substrate, operative in accordance with another embodiment of the disclosed technique.

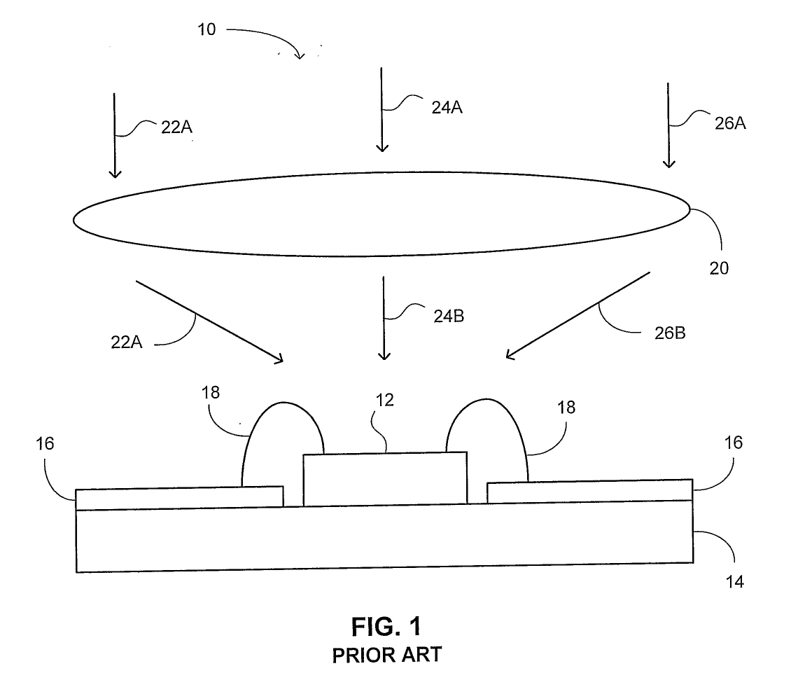

### DETAILED DESCRIPTION OF THE EMBODIMENTS

The disclosed technique overcomes the disadvantages of the prior art by providing a method for calculating the number of photovoltaic arrays composed of chip-sized photovoltaic cells, which can be cut out of a photovoltaic wafer for constructing a monolithic low concentration concentrating photovoltaic panel based on crossed compound parabolic concentrators. A concentrating photovoltaic panel includes an array of photovoltaic cells and a corresponding array of concentrators. The disclosed technique further provides a method for separating the arrays of photovoltaic cells out of the cut photovoltaic wafer. The number of photovoltaic arrays is determined according to the index of refraction, and according to the field of view, of the array of concentrators.

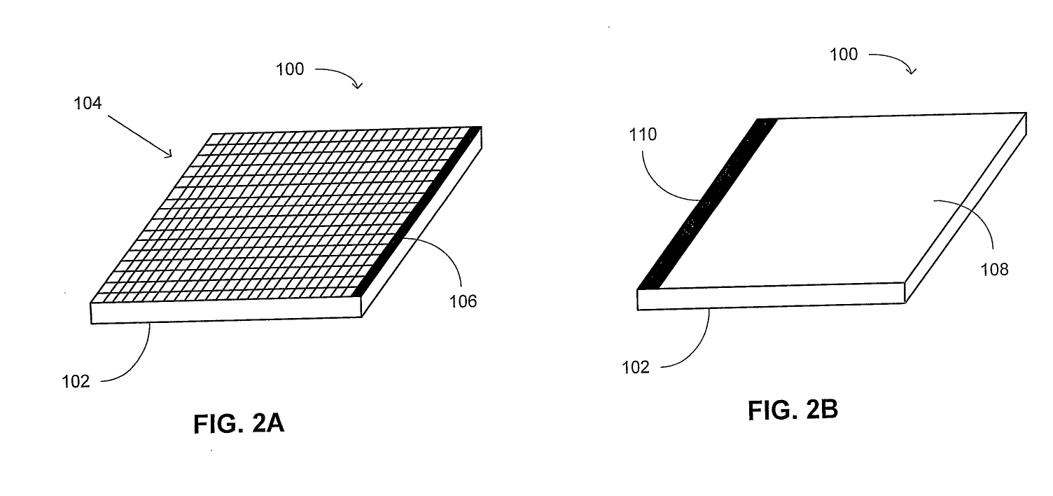

Reference is now made to FIGS. 2A and 2B. FIG. 2A is a schematic illustration of a top isometric view of a concentrating photovoltaic panel, generally referenced 100, constructed and operative in accordance with an embodiment of the disclosed technique. FIG. 2B is a schematic illustration of a bottom isometric view of the photovoltaic concentrating panel of FIG. 2A. Photovoltaic panel 100 includes a polymer encapsulating layer 102, an optical layer 104, a peripheral top contact pad 106, a protective polymer layer 108, and a peripheral bottom contact pad 110. Optical layer 104 covers the top surface (not shown) of encapsulating polymer layer 102. Peripheral top contact pad 106 is positioned on the periphery of the top surface of polymer layer 102, adjacent to optical layer 104. In the example set forth in FIG. 2A, contact pad 106 is positioned on the right hand side of the top surface of polymer layer 102, and along the right hand side of optical layer 104.

Polymer encapsulating layer 102 encapsulates a plurality of photovoltaic cells (not shown), which are embedded therein. Optical layer 104 includes a plurality of crossed Compound Parabolic Concentrators (CPCs). A plurality of interconnects (not shown) are embedded between polymer encapsulating layer 102 and optical layer 104. Periphery contact pad 106 is made of an electrically conductive material, such as copper, aluminum, and the like. Periphery contact pad 106 provides an electrical connection for photovoltaic panel 100 (e.g., periphery top contact pad 106 connects photovoltaic panel 100 to an external system, such as an electrical power grid).

Photovoltaic panel 100 further includes a protective layer 108 and a periphery bottom contact pad 110. Protective layer 108 is positioned on the bottom surface (not shown) of encapsulating polymer layer 102. Periphery bottom contact pad 110 is positioned on the periphery of the bottom surface of encapsulating polymer layer 102, adjacent protective layer 108. In the example set forth in FIG. 2B, periphery bottom contact pad 110 is positioned on the left hand side of protective layer 108.

Protective layer 108 covers the bottom side of photovoltaic panel 100 and provides environmental protection thereto. Periphery bottom contact pad 110 is made of electrically conductive material, such as copper, aluminum and the like. Periphery bottom contact pad 110 connects photovoltaic panel 100 to an external system (e.g., an electrical power grid).

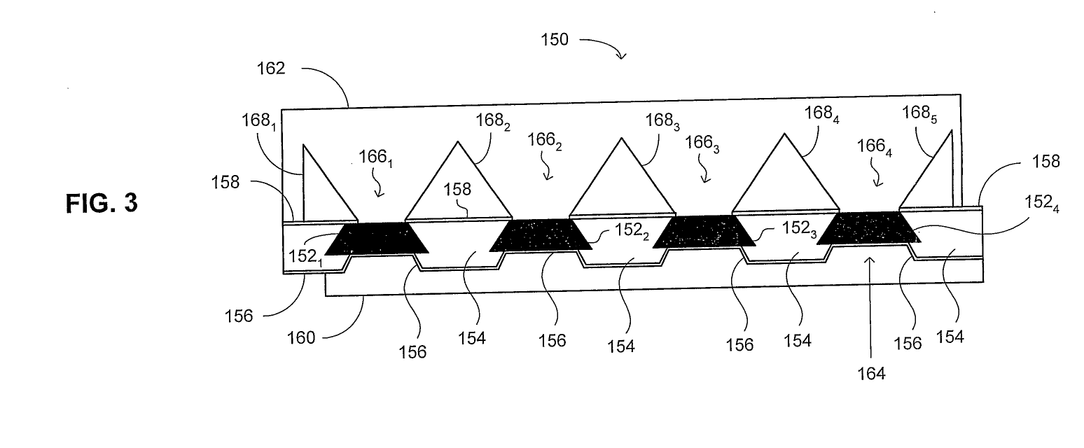

Reference is now made to FIG. 3, which is a schematic illustration of a cross section view of a concentrating photovoltaic panel, generally referenced 150, constructed and operative in accordance with another embodiment of the disclosed technique. Photovoltaic panel 150 includes an array of four photovoltaic cells 152₁, 152₂, 152₃ and 152₄, an encapsulating polymer layer 154, a bottom interconnects layer 156, a top interconnects layer 158, a bottom protective layer 160 and an optical layer 162. Each of photovoltaic cells 152₁, 152₂, 152₃ and 152₄ is embedded within encapsulating layer 154. Bottom interconnects layer 156 is coupled with the bottom surfaces (not shown) of both photovoltaic cells 152₁, 152₂, 152₃ and 152₄ and of encapsulating layer 154 (i.e., bottom interconnects layer 156 electrically interconnect the bottom surfaces of photovoltaic cells 152₁, 152₂, 152₃ and 152₄). Top interconnects layer 158 is coupled between photovoltaic cells 152₁, 152₂, 152₃ and 152₄ at the top surfaces thereof (i.e., top interconnects layer 158 electrically interconnect the top surfaces of photovoltaic cells 152₁, 152₂, 152₃ and 152₄). Encapsulating polymer layer 154 is coupled between protective layer 160 (i.e., which covers the bottom of bottom interconnects layer 156) and optical layer 162 (i.e., which covers the top of top interconnects layer 158).

Each of Photovoltaic cells 152₁, 152₂, 152₃ and 152₄ is a chip-sized photovoltaic cell. Encapsulating polymer layer 154 is made of a polymer such as polyolefin-based block copolymers, and the like. Encapsulating polymer layer 154 maintains photovoltaic cells 152₁, 152₂, 152₃ and 152₄ in position and supports bottom interconnects layer 156 and top interconnects layer 158. Encapsulating layer 154 absorbs stresses arising from mismatches of thermal expansion coefficients between components of photovoltaic panel 150 (e.g., photovoltaic cells 152₁, 152₂, 152₃ and 152₄ and bottom interconnects layer 156). Encapsulating layer 154 encapsulates photovoltaic cells 152₁, 152₂, 152₃ and 152₄, which are embedded therein. In other words, encapsulating layer 154 covers all sides, and partially the bottom surface (not shown) of each of photovoltaic cells 152₁, 152₂, 152₃ and 152₄.

Bottom interconnects layer 156 is made of an electrically conductive metal, such as copper, aluminum, tungsten and the like. Alternatively, bottom interconnects layer 156 is made of an electrically conductive metal stack, such as nickel-copper and the like. As detailed herein above, bottom interconnects layer 156 is coupled with the bottom surface (not shown) of encapsulating layer 154, and with the exposed areas of the bottom surface (not shown) of photovoltaic cells 152₁, 152₂, 152₃ and 152₄. Bottom interconnects layer 156 electrically interconnects the bottom surfaces of all photovoltaic cells 152₁, 152₂, 152₃ and 152₄. Bottom interconnects layer 156 thermally interconnects photovoltaic cells 152₁, 152₂, 152₃ and 152₄ and conduct excess heat out of photovoltaic panel 150. In other words, bottom interconnects layer 156 further functions as a heat sink for photovoltaic panel 150.

Top interconnects layer 158 is made of an electrically conductive metal, such as copper, aluminum and the like. Alternatively, Top interconnects layer 158 is made of an electrically conductive metal stack, such as nickel-copper and the like. Top interconnects layer 158 is coupled with the top surface (not shown) of encapsulating layer 154, and with the exposed edges on the top surface of photovoltaic cells 152₁, 152₂, 152₃ and 152₄). Top interconnects layer 158 electrically interconnects the top surfaces of all photovoltaic cells 152₁, 152₂, 152₃ and 152₄.

Protective layer 160 is made of a protective polymer such as Polyvinylidene Fluoride (PVDF), polymethyl methacrylate, polycarbonate and the like. Alternatively protective layer 160 is made of a protective composite material such as fiberglass, glass filler epoxy or ceramic filler epoxy. Protective layer 160 covers the bottom side of photovoltaic panel 150 (i.e., bottom interconnects layer 156) and provides environmental protection thereto. One end of bottom interconnects layer 156 remains exposed such that it provides an electrical connection to an external electrical system (e.g., a power grid). In the example set forth in FIG. 3, the left hand side end of bottom interconnects layer 156 remains exposed, and is not covered by protective layer 160. Alternatively, a plurality of locations of bottom interconnects layer 156 are exposed, thereby providing additional electrical connections.

Optical layer 162 covers top interconnects layer 158. One end of top interconnects layer 158 is exposed, such that it provides an electrical connection to external electrical system. Alternatively, a plurality of locations of top interconnects layer 158 are exposed, thereby providing additional electrical connections. It is noted that, top interconnects layer 158 and bottom interconnects layer 156 electrically interconnect photovoltaic cells 152₁, 152₂, 152₃ and 152₄ in-parallel, or in-series.

Optical layer 162 is made of optically transparent polymers having a high index of refraction such as polymethyl methacrylate, polycarbonate, and the like. Optical layer 162 includes an array of inverted truncated triangles 166₁, 166₂, 166₃ and 166₄ (i.e., CPCs 166₁, 166₂, 166₃ and 166₄). Each of CPCs 166₁, 166₂, 166₃ and 166₄ is positioned on top of each of photovoltaic cell 152₁, 152₂, 152₃ and 152₄, respectively. The volume between CPCs 166₁, 166₂, 166₃ and 166₄ is of the shape of an array of hollow triangles 168₁, 168₂, 168₃, 168₄ and 168₅. The truncated end (i.e., the exit aperture—not shown) of each of CPCs 166₁, 166₂, 166₃ and 166₄ is positioned adjacent to the top surface of each of photovoltaic cells 152₁, 152₂, 152₃ and 152₄, respectively, and is optically coupled therewith. The refraction index of each of CPCs 166₁, 166₂, 166₃ and 166₄ is higher than that of each of hollow triangles 168₁, 168₂, 168₃, 168₄ and 168₅. In this manner, each CPC 166₁, 166₂, 166₃ and 166₄ concentrates light onto each of photovoltaic cells 152₁, 152₂, 152₃ and 152₄, respectively, by total internal reflection. Alternatively, at least a portion of array of hollow triangles 168₁, 168₂, 168₃, 168₄ and 168₅ is replaced by triangles filled with a material having refraction index lower than that of optical layer 162. Alternatively, photovoltaic panel 150 includes any number of photovoltaic cells, CPCs, and hollow triangles, such as hundred, thousand, and ten thousand photovoltaic cells and respective CPCs.

A layer of vias 164 is etched through encapsulating layer 154. The position of each via of vias layer 164 corresponds to the position of a respective one of photovoltaic cells 152₁, 152₂, 152₃ and 152₄. Each via 164 exposes (i,e., vias 164 provide openings through encapsulating layer 154, thereby exposing photovoltaic cells 152₁, 152₂, 152₃ and 152₄ out of encapsulating layer 154) a portion of the bottom surface (not shown) of the respective one of photovoltaic cells 152₁, 152₂, 152₃ and 152₄. Light radiation enters photovoltaic panel 150 through the top surface (not shown) of optical layer 162. The light is concentrated through total internal reflection by each of CPCs 166₁, 166₂, 166₃ and 166₄. The concentrated light exits optical layer 162 toward the top surface of photovoltaic cells 152₁, 152₂, 152₃ and 152₄, respectively. Each of photovoltaic cells 152₁, 152₂, 152₃ and 152₄ converts the solar radiation into electrical current. Bottom interconnects layer 156 and top interconnects layer 158 conduct the electrical current from photovoltaic cells 152₁, 152₂, 152₃ and 152₄ to the electrical connections of photovoltaic panel 150. Bottom interconnects layer 156 further conducts heat away photovoltaic panel 150.

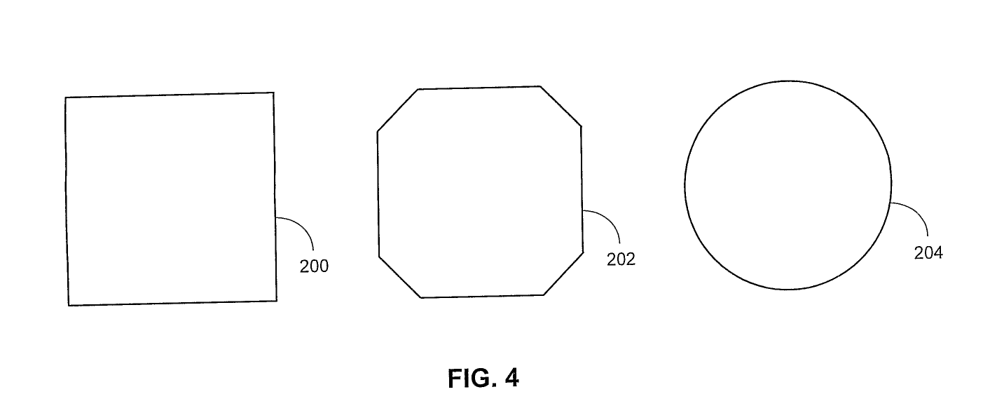

It is noted that, each CPC is optically coupled to a chip-sized photovoltaic cell (i.e., the optical exit aperture of each CPC is positioned adjacent to the optical entrance surface of the respective chip-sized photovoltaic cell). A single, low concentration, photovoltaic panel may include large numbers of chip-sized photovoltaic cells and respective CPCs (i.e., from hundreds to tens of thousands). The chip-sized photovoltaic cells are cut out of a wafer size photovoltaic cell. Reference is now made to FIG. 4, which is a schematic illustration of three wafer-size photovoltaic cells, generally referenced 200, 202 and 204, constructed and operative in accordance with a further embodiment of the disclosed technique. Wafer-size photovoltaic cell 200 is in the shape of a square. Wafer-size photovoltaic cell 202 is in the shape of a pseudo-square (i.e., a square having truncated corners). Wafer-size photovoltaic cell 204 is in the shape of a circle.

Each of wafer-size photovoltaic cells 200, 202 and 204, is either a mono-crystalline or a poly-crystalline photovoltaic cell. Each of wafer-size photovoltaic cells 200, 202 and 204, is made of a semiconductor, such as Silicon (Si), Gallium-Arsenide (GaAs), and the like. The dimension of each of wafer-size photovoltaic cells 200, 202 and 204 (i.e., the size of one side) ranges between approximately 2.5 and 50 centimeters (i.e., as is customary in the art). The thickness of each of wafer-size photovoltaic cells 200, 202 and 204, ranges between 100 micrometers to one millimeter. The top surfaces of each of wafer-size photovoltaic cells 200, 202 and 204 are either smooth or textured. Each of wafer-size photovoltaic cells 200, 202 and 204 includes a passivation layer, made of Silicon Nitride (SiN) or Silicon Oxide (SiO), on the top surface thereof.

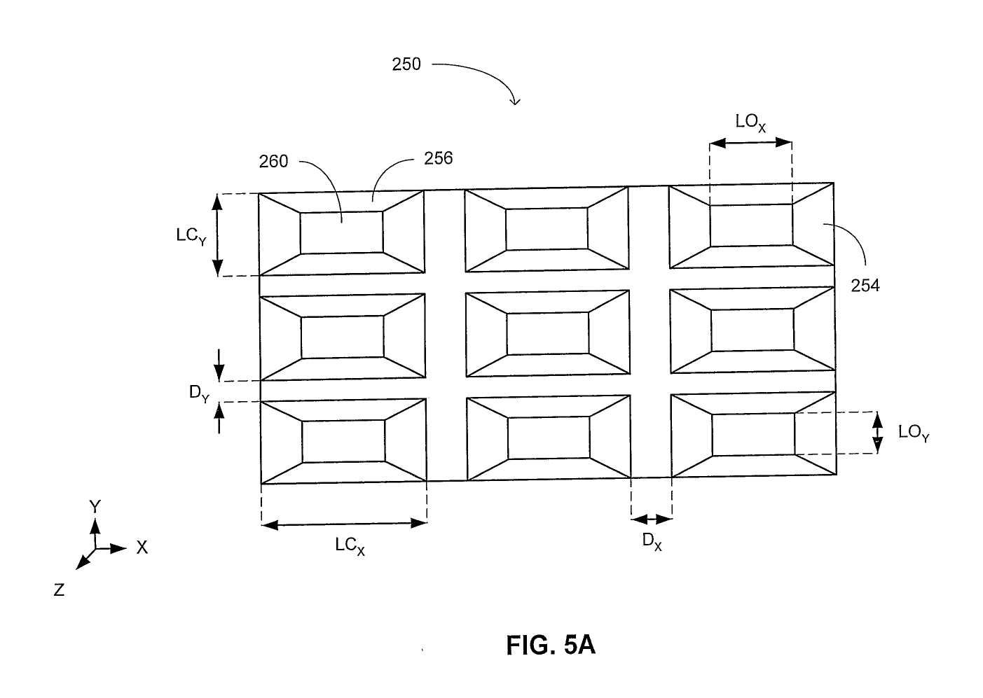

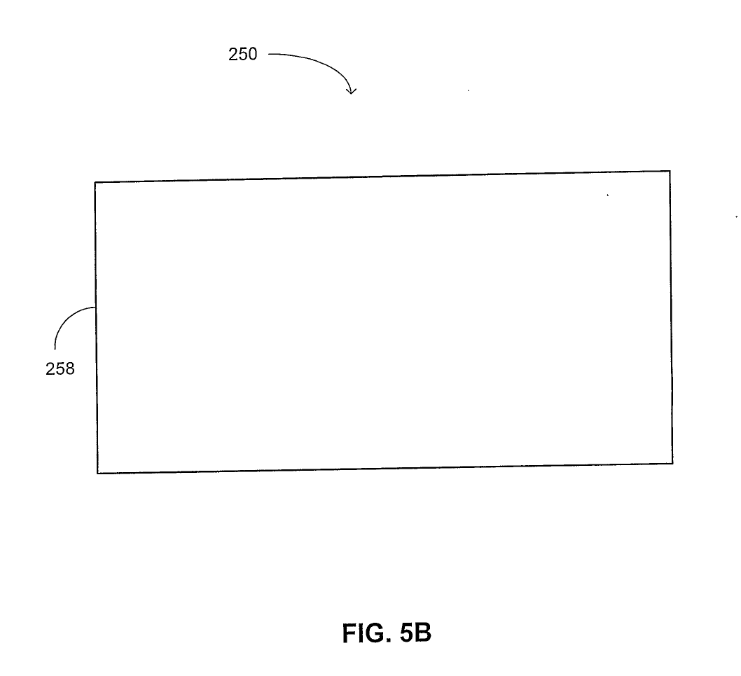

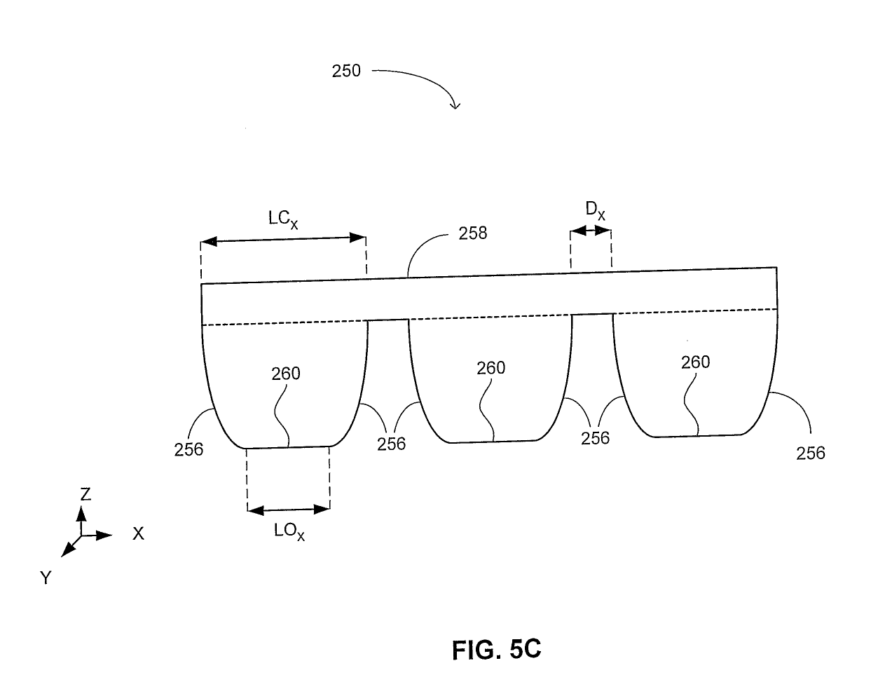

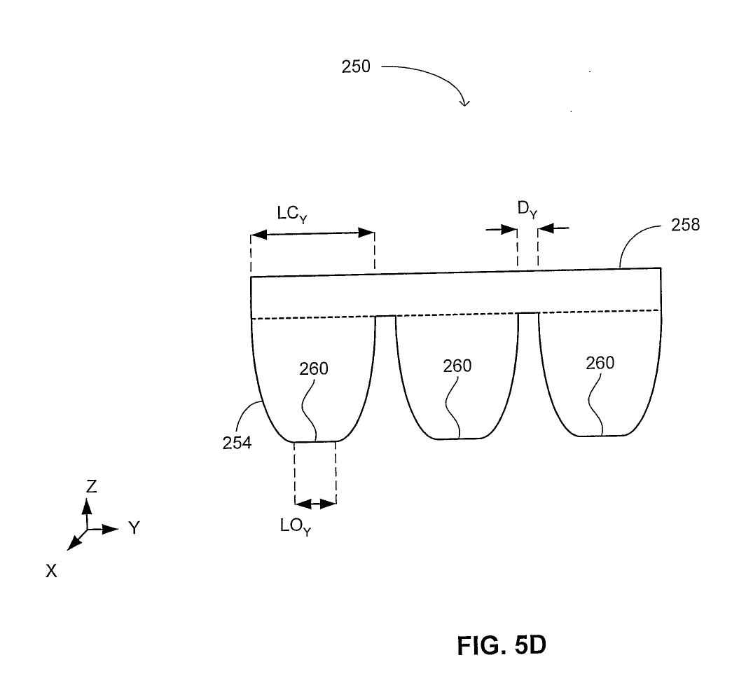

Reference is now made to FIGS. 5A, 5B, 5C and 5D. FIG. 5A is a schematic illustration of a bottom view of a portion of an optical layer, generally referenced 250, including six crossed CPCs, constructed and operative in accordance with another embodiment of the disclosed technique. FIG. 5B is a schematic illustration of a top view of the portion of the optical layer of FIG. 5A. FIG. 5C is a schematic illustration of a cross section of a ZX plane of the portion of the optical layer of FIG. 5A. FIG. 5D is a schematic illustration of a cross section of a ZY plane of the portion of the optical layer of FIG. 5A.

Optical layer 250 includes a plurality of optical exit apertures 260, a plurality of crossed CPCs (not shown), and a flat top surface 258 (FIG. 5B). Each of the CPCs includes two X axis side walls 256 and two Y axis side walls 254. The length of the X axis of the optical exit aperture of each of the CPCs is Lo_{X}. The length of the Y axis of the optical exit aperture of each of the CPCs is Lo_{Y}. The length of the X axis of the optical entry aperture of each of the CPCs is Lc_{X}. The length of the Y axis of the optical entry aperture of each of the CPCs is Lc_{Y}. A length D_{X} is the distance separating the entry apertures of two adjacent CPCs along the X axis. A length D_{Y} is the distance separating the entry apertures of two adjacent CPCs along the Y axis.

As depicted in FIGS. 5C and 5D, each of X axis side walls 256 and Y axis side walls 254 is of parabolic shape (i.e., has a radius of curvature). Light enters optical layer 250 through top flat surface 258. The light is reflected by total internal reflection from side walls 254 and 256. The concentrated light (i.e., the light which entered optical layer 250 and was internally reflected therein) exits the CPCs through optically exit surfaces 260.

C_{geo} is defined as the geometrical concentration factor of the crossed CPCs (i.e., the ratio between the surface area of the CPC optical entrance to the surface area of the CPC optical exit). C_{geoX} is the geometrical concentration factor of the crossed CPCs in the X axis (i.e., the ratio between length Lc_{X} and the length Lo_{X}). C_{geoY} is the geometrical concentration factor of the crossed CPCs in the Y axis (i.e., the ratio between length Lc_{Y} and the length Lo_{Y}). C_{geo}, C_{geoX} and C_{geoY} can further be expressed in terms of the index of refraction of the material of the CPCs and in terms of the X axis and Y axis field of view angles, α_{X} and α_{Y}, respectively.

C_{geoX}=n/sin(α_{X}/2) (1)

C_{geoY}=n/sin(α_{Y}/2) (2)

C_{geo}=C_{geoX}*C_{geoY} (3)

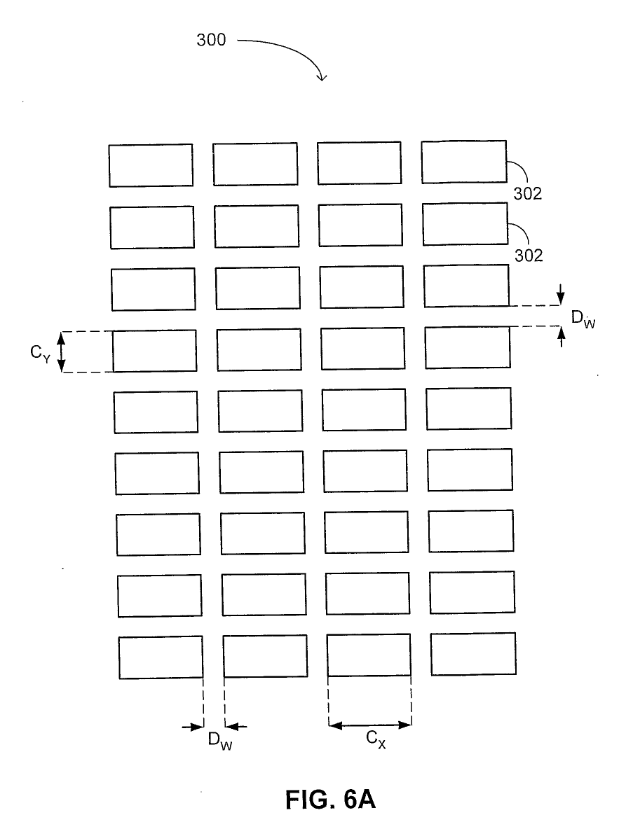

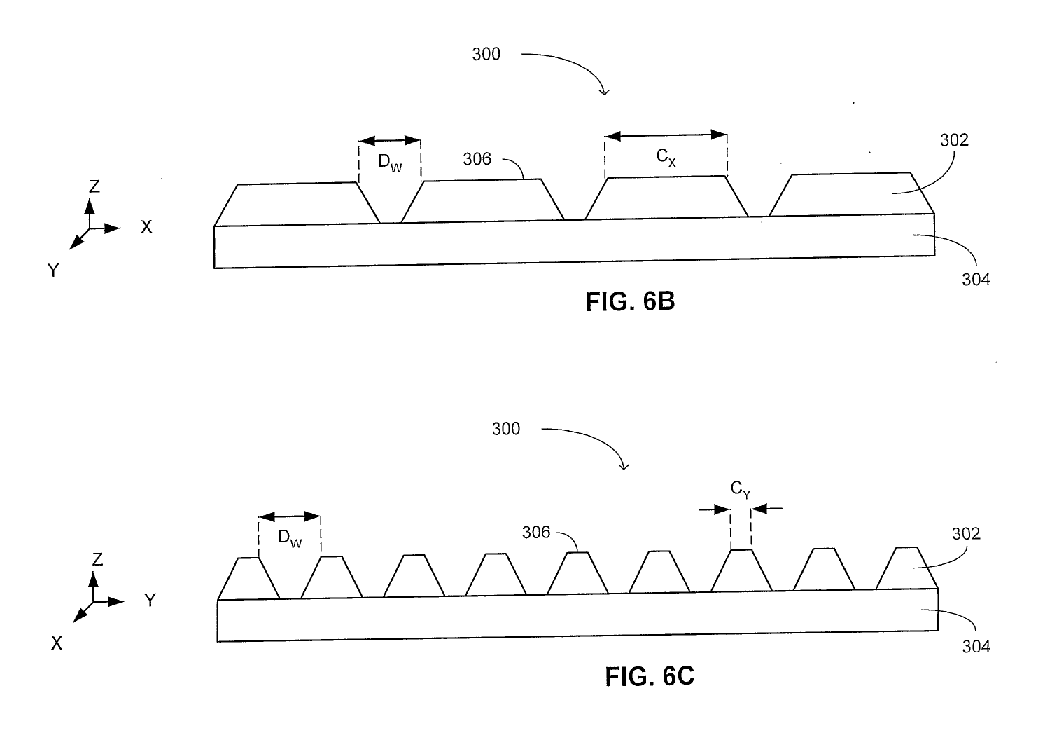

Reference is now made to FIGS. 6A, 6B and 6C. FIG. 6A is a schematic illustration of a portion of a wafer-sized photovoltaic cell, generally referenced 300, diced into a plurality of chip-sized photovoltaic cells, constructed and operative in accordance with a further embodiment of the disclosed technique. FIG. 6B is a schematic illustration of a cross section of a ZX plane of the wafer-sized photovoltaic cell of FIG. 6A. FIG. 6C is a schematic illustration of a cross section of a ZY plane of the wafer-sized photovoltaic cell of FIG. 6A. Wafer-size photovoltaic cell 300 includes a plurality of chip-sized photovoltaic cells 302 and a dicing tape layer 304. Wafer-size photovoltaic cell 300 is bonded on top of dicing tape layer 304. In this manner, each of chip-size photovoltaic cells 302 is bonded on top of dicing tape layer 304.

Dicing tape layer 304 is either a UV sensitive dicing tape, or a non-UV sensitive dicing tape. A length D_{W} is the dicing width at a top surface 306 of each of chip-size photovoltaic cells 302. It is noted that dicing width D_{W} is similar for both the X axis and the Y axis (i.e., employing a single blade for dicing both axes). Alternatively, the dicing width in the X axis is different than that of the Y axis (i.e., an X axis dicing width D_{WX} and a Y axis dicing width D_{WY} are different). A length C_{X} is the length along the X axis, at top surface 306, of each of chip-size photovoltaic cells 302. A length C_{Y} is the length along the Y axis, at top surface 306, of each of chip-size photovoltaic cells 302. The lengths C_{X} and C_{Y} are given by the following equations:

C_{X}=[(Lc_{X}+D_{X})/Int(n/sin(α_{X}/2))]−D_{W} (4)

C_{Y}=[(Lc_{Y}+D_{Y})/Int(n/sin(α_{Y}/2))]−D_{W} (5)

In case of chip-size photovoltaic cells 302 having both top and bottom contacts, the dicing width D_{W} is chosen such that C_{X}>Lo_{X} and C_{Y}>Lo_{Y}. In case of chip-size photovoltaic cells 302 having only bottom contacts, the dicing width D_{W} is chosen such that C_{X}≧Lo_{X} and C_{Y}≧Lo_{Y}.

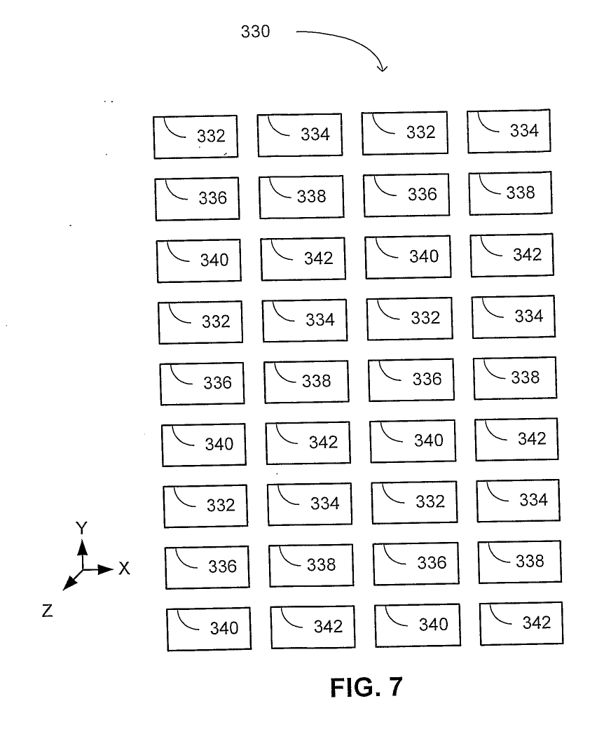

Reference is now made to FIG. 7, which is a schematic illustration of a portion of a wafer-sized photovoltaic cell, generally referenced 330, diced into a plurality of chip-sized photovoltaic cells, constructed and operative in accordance with another embodiment of the disclosed technique. Wafer-size photovoltaic cell 330 includes a first array of chip-size photovoltaic cells 332, a second array of chip-size photovoltaic cells 334, a third array of chip-size photovoltaic cells 336, a fourth array of chip-size photovoltaic cells 338, a fifth array of chip-size photovoltaic cells 340 and a sixth array of chip-size photovoltaic cells 342.

In the example set forth in FIG. 7, wafer-size photovoltaic cell 330 is diced into six arrays of chip-size photovoltaic cells. Alternatively, wafer-size photovoltaic cell 330 is diced into any number of chip-size photovoltaic cells, as determined by the following equation:

Number of arrays=Int(n/sin(α_{X}/2))*Int(n/sin(α_{y}/2)). (6)

It is noted that the number of arrays relates to the optical characteristics of the concentrators (i.e., index of refraction and field of view angles) and not to the size of the photovoltaic wafer. The number of arrays is thus related to the optimal size of the chip-size photovoltaic cells and to the distances between adjacent cells.

Detailed in table 2, herein below, are the number of chip-size photovoltaic cells arrays as given by equation (6), for n=1.49, and for various ranges of angles of filed of view in the X and Y axes.

| Field of view angle | 180-96.3 | 96.3-59.6 | 59.6-43.7 | 43.7-34.7 | 34.7-28.8 | 28.8-24.6 | 24.6-21.5 | 21.5-19.1 | 19.1-17.1 |
|---|---|---|---|---|---|---|---|---|---|
| 180-96.3 | 1 | 2 | 3 | 4 | 5 | 6 | 7 | 8 | 9 |
| 96.3-59.6 | 2 | 4 | 6 | 8 | 10 | 12 | 14 | 16 | 18 |
| 59.6-43.7 | 3 | 6 | 3 | 12 | 15 | 18 | 21 | 24 | 27 |
| 43.7-34.7 | 4 | 8 | 12 | 16 | 20 | 24 | 28 | 32 | 36 |
| 34.7-28.8 | 5 | 10 | 15 | 20 | 25 | 30 | 35 | 40 | 45 |
| 28.8-24.6 | 6 | 12 | 18 | 24 | 30 | 36 | 42 | 48 | 54 |
| 24.6-21.5 | 7 | 14 | 21 | 28 | 35 | 42 | 49 | 56 | 63 |
| 21.5-19.1 | 8 | 16 | 24 | 32 | 40 | 48 | 56 | 64 | 72 |
| 19.1-17.1 | 9 | 18 | 27 | 36 | 45 | 54 | 63 | 72 | 81 |

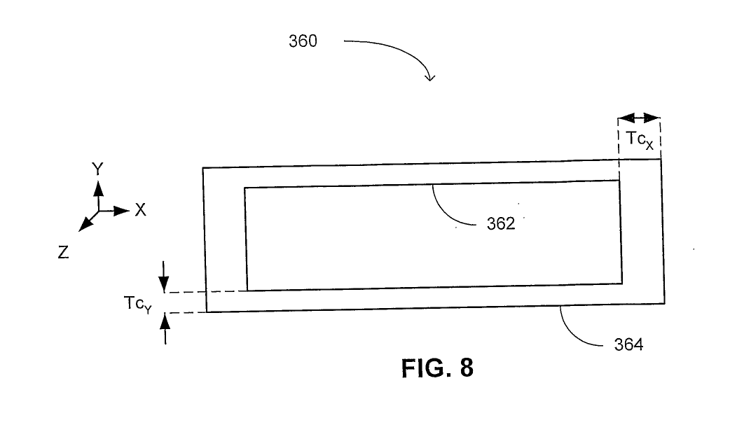

Reference is now made to FIG. 8, which is a schematic illustration of a top view of a chip-size photovoltaic cell, generally referenced 360, including both a top contact and a bottom contact, constructed and operative in accordance with a further embodiment of the disclosed technique. Chip-size photovoltaic cell 360 includes a passivation layer 362 and an emitter layer 364. Passivation layer 362 is made of SiN, SiOx, and the like. Emitter layer 364 is either a P type doped, or an N type doped, Silicon layer. A length Tc_{X} is the top contact width in the X axis. A length Tc_{Y} is the top contact width in the Y axis. Lengths Tc_{X} and Tc_{Y} are given by the following equations, respectively:

Tc_{X}=(C_{X}−Lo_{X})/2 (7)

Tc_{Y}=(C_{Y}−Lo_{Y})/2 (8)

Detailed herein is a numerical example for the application of the above equations. Assuming that, n=1.49, Lc_{X}=7.74 mm, Lc_{Y}=5.25 mm, Lo_{X}=3.5 mm, Lo_{Y}=1.54 mm, D_{X}=D_{Y}=0.1 mm, α_{X}=84.8⁰, α_{Y}=51.8⁰ and D_{W}=0.06 mm. Solving equations (4), (5), (6), (7) and (8), respectively, for the above numerical values results in the following chip-size photovoltaic cell parameters, C_{X}=3.86 mm, C_{Y}=1.72 mm, the number of arrays is six, Tc_{X}=0.18 mm and Tc_{Y}=0.09 mm.

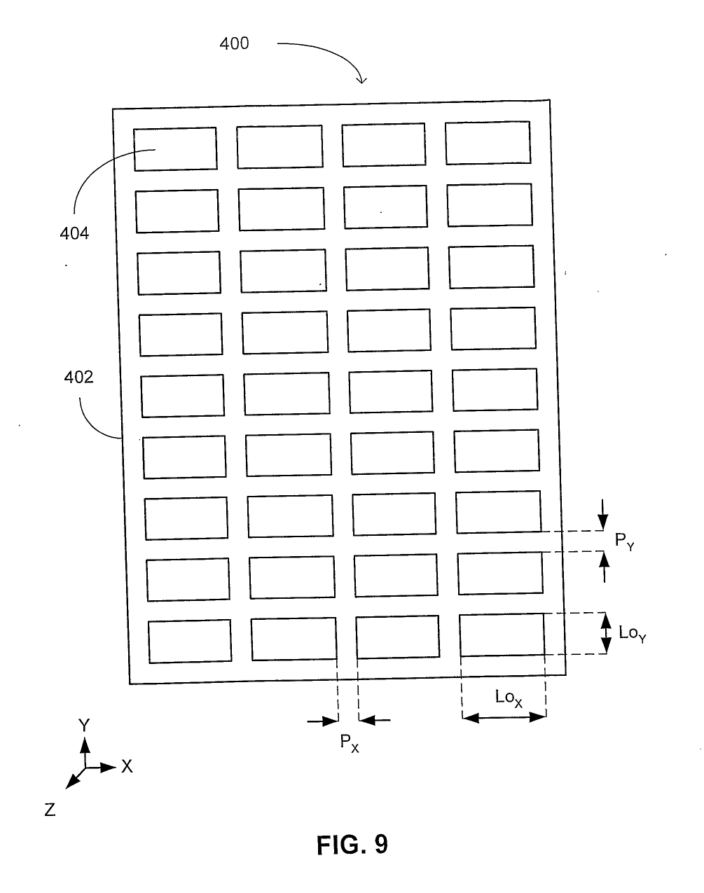

Reference is now made to FIG. 9, which is a schematic illustration of a top view of a portion of a wafer-size photovoltaic cell, generally referenced 400, after the deposition of a passivation layer, constructed and operative in accordance with another embodiment of the disclosed technique. Wafer-size photovoltaic cell 400 includes a passivation layer 404 and an exposed emitter layer 402. Passivation layer 404 is deposited on the top surface of wafer-size photovoltaic cell 400. Passivation layer 404 is made of SiN, SiOx, and the like. Passivation layer 404 is in the shape of a plurality of rectangular islands on top of the top surface of wafer-size photovoltaic cell 400. Exposed emitter layer 402 is either P type doped layer, or an N type doped layer.

A length Lo_{X} is the length along the X axis of the optical exit aperture of a crossed CPC. A length Lo_{Y} is the length along the Y axis of the optical exit aperture of a crossed CPC. A length P_{X} is the distance along the X axis between islands of passivation layer 404. A length P_{Y} is the distance along the Y axis between islands of passivation layer 404. P_{X} and P_{Y} are given by the following equations, respectively.

P_{X}=C_{X}−Lo_{X}+D_{W} (9)

P_{Y}=C_{Y}−Lo_{Y}+D_{W} (10)

After dicing of the wafer size photovoltaic cell (e.g., cell 300 of FIGS. 6A, 6B and 6C), the individual chip-size photovoltaic cells (e.g., cells 302 of FIGS. 6A, 6B and 6C) are bonded onto a dicing tape (e.g., tape 304 of FIGS. 6A, 6B and 6C). The individual chip-size photovoltaic cells are arranged in a plurality of arrays (e.g., six arrays 332-342 of FIG. 7). Each of the chip-size photovoltaic cells arrays corresponds (i.e., matches in spatial configuration) to the spatial configuration of the optical layer (e.g., optical layer 162 of FIG. 3A). Detailed herein below are examples of three methods for separating the chip-size photovoltaic cells arrays and transferring the arrays to a supporting substrate for forming a concentrating photovoltaic panel.

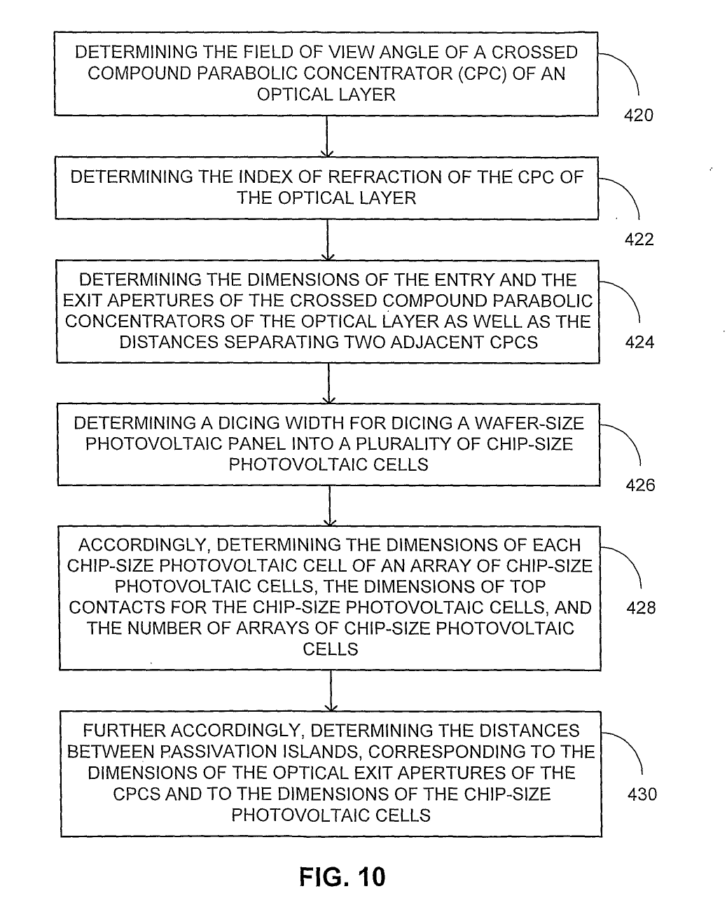

Reference is now made to FIG. 10, which is a block diagram illustration of a method for determining the dimensions of a chip-size photovoltaic cell and the number of arrays of such chip-size photovoltaic cells, operative in accordance with a further embodiment of the disclosed technique. In procedure 420, the field of view angle of a crossed compound parabolic concentrator (CPC) of an optical layer is determined. It is noted that, the field of view angles for the X axis and for the Y axis might be different and should both be determined. With reference to FIGS. 5A-5D, the X axis and Y axis field of view angles, α_{X} and α_{Y} of the CPCs of optical layer 250 are determined. In procedure 422, the index of refraction of the CPC of the optical layer is determined. With reference to FIGS. 5A-5D, the index of refraction of optical layer 250 is determined.

In procedure 424, the dimensions of the entry and the exit apertures of the crossed compound parabolic concentrators of the optical layer are determined, as well as the distances separating two adjacent CPCs. With reference to FIGS. 5A-5D, The length of the X axis of the optical exit aperture of each of the CPCs is Lo_{X}. The length of the Y axis of the optical exit aperture of each of the CPCs is Lo_{Y}. The length of the X axis of the optical entry aperture of each of the CPCs is Lc_{X}. The length of the Y axis of the optical entry aperture of each of the CPCs is Lc_{Y}. A length D_{X} is the distance separating the entry apertures of two adjacent CPCs along the X axis. A length D_{Y} is the distance separating the entry apertures of two adjacent CPCs along the Y axis.

In procedure 426, a dicing width for dicing a wafer-size photovoltaic panel into a plurality of chip-size photovoltaic cells is determined. With reference to FIGS. 6A-6C, In case of chip-size photovoltaic cells 302 having both top and bottom contacts, the dicing width D_{W} is chosen such that C_{X}>Lo_{X} and C_{Y}>Lo_{Y}. In case of chip-size photovoltaic cells 302 having only bottom contacts, the dicing width D_{W} is chosen such that C_{X}≧Lo_{X} and C_{Y}≧Lo_{Y}.

In procedure 428, accordingly, the dimensions of each chip-size photovoltaic cell of an array of chip-size photovoltaic cells, the dimensions of top contacts for the chip-size photovoltaic cells, and the number of arrays of chip-size photovoltaic cells are determined. With reference to FIGS. 5A-5D, 6A-6C, 7 and 8, the dimensions of each chip-size photovoltaic cell of an array of chip-size photovoltaic cells, the dimensions of top contacts for the chip-size photovoltaic cells, and the number of arrays of chip-size photovoltaic cells are determined are determined in accordance with equations (4), (5), (6), (7) and (8).

In procedure 430, further accordingly, the distances between passivation islands, corresponding to the dimensions of the optical exit apertures of the CPCs and to the dimensions of the chip-size photovoltaic cells are determined. With reference to FIG. 9, the distances between passivation islands, corresponding to the dimensions of the optical exit apertures of the CPCs and to the dimensions of the chip-size photovoltaic cells are determined in accordance with equations (9) and (10).

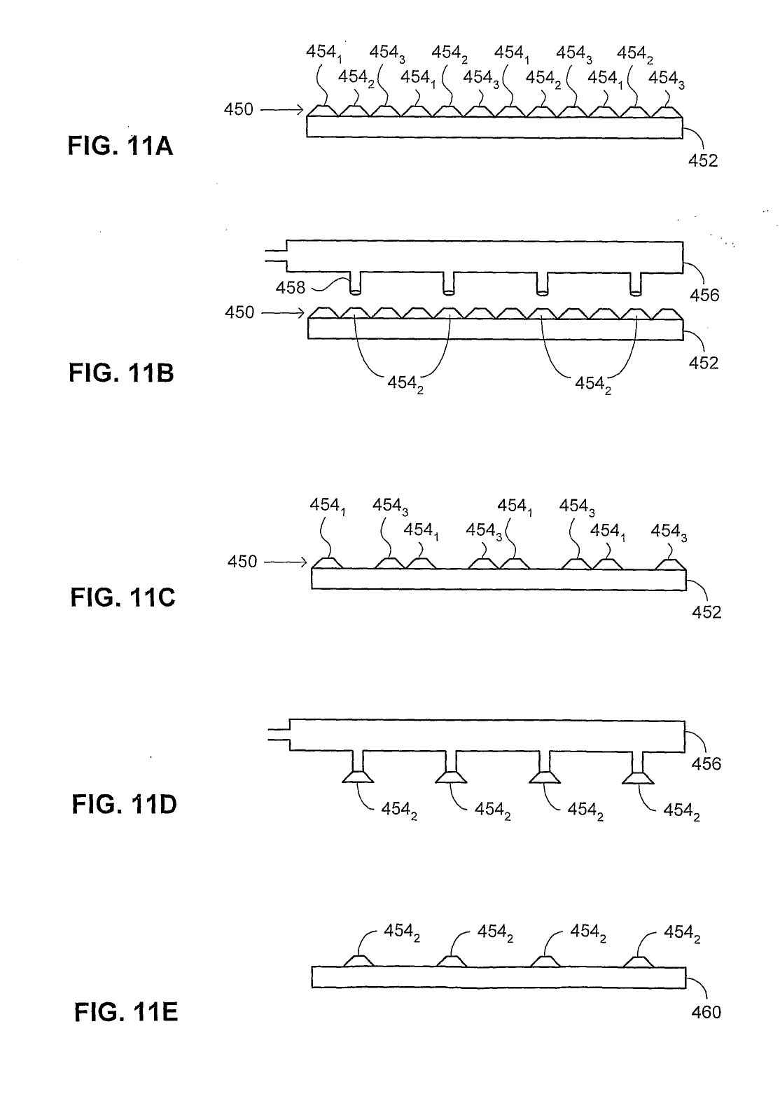

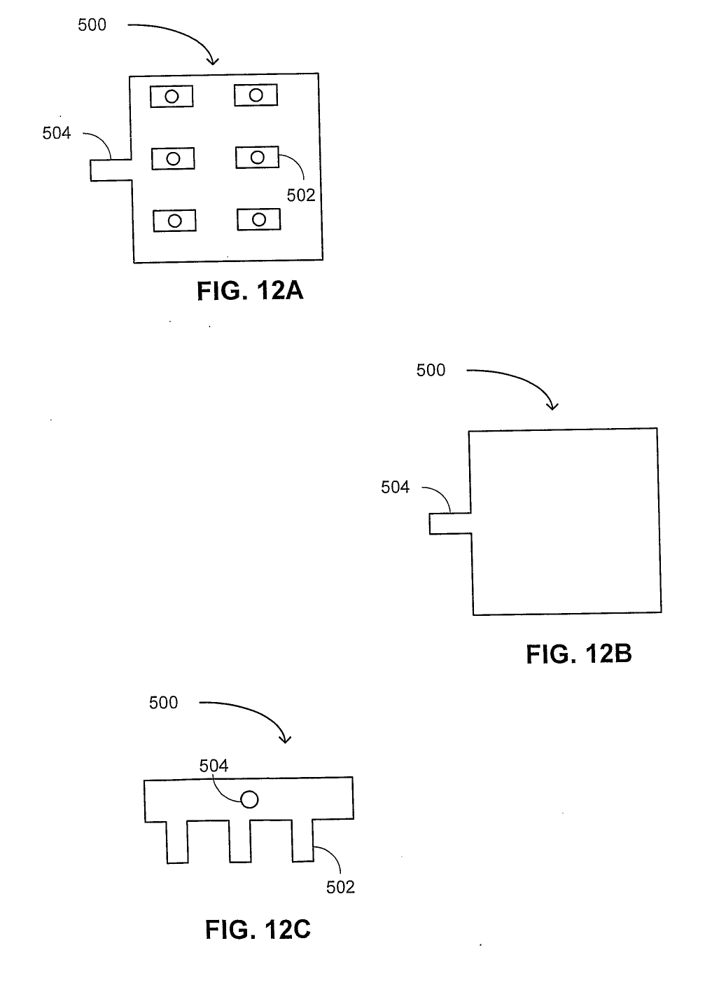

Detailed herein below, are a plurality of methods for separating an array of chip-sized photovoltaic cells out of a photovoltaic wafer, and transferring the array onto a support substrate. A first method for separating an array of chip-sized photovoltaic cells and transferring the array is detailed herein below with reference to FIGS. 11A-11E, and 12A-12C. Reference is now made to FIGS. 11A, 11B, 11C, 11D, and 11E, which are schematic illustrations of the steps for performing a first method for separating an array of chip-size photovoltaic cells, diced out of a wafer-size photovoltaic panel, and transferring the array onto a support substrate, operative in accordance with another embodiment of the disclosed technique.

With reference to FIG. 11A, a wafer-size photovoltaic cell 450 is coupled with a non-UV sensitive dicing tape 452 (e.g., Wafer-size photovoltaic cell 300 and dicing tape layer 304 of FIGS. 6A-6C). Wafer-size photovoltaic cell 450 is diced into three arrays of chip-size photovoltaic cells 454₁, 454₂ and 454₃ (e.g., chip-size photovoltaic cells 302 of FIGS. 6A-6C). The dimensions of each of the photovoltaic cells of the pluralities of chip-size photovoltaic cells 454₁, 454₂ and 454₃, as well as the number of arrays of chip-size cells and the dimensions of the respective top contacts are determined in accordance with the disclosed technique (i.e., equations 4, 5, 6, 7 and 8).

With reference to FIG. 11B, a multi-head vacuum jig 456 includes a plurality of vacuum heads 458. The position of each of vacuum heads 458 along vacuum jig 456 corresponds to the position of a respective photovoltaic cell of a selected one of the pluralities of chip-size photovoltaic cells 454₁, 454₂ and 454₃. In the example set forth in FIG. 11B, each of vacuum heads 458 is positioned above each photovoltaic cell of array of chip-size photovoltaic cells 454₂.

With reference to FIG. 11C, after the transfer of array of chip-size photovoltaic cells 454₂, wafer-size photovoltaic panel 450 includes two arrays of chip-size photovoltaic cells 454₁ and 454₃. With reference to FIG. 11D, Multi-head vacuum jig 456 picks up array of chip-size photovoltaic cells 454₂. With reference to FIG. 11E, Multi-head vacuum jig 456 transfers array of chip-size photovoltaic cells 454₂. Multi-head vacuum jig 456 places array of chip-size photovoltaic cells 454₂ on a support substrate 460.

It is noted that the steps detailed herein above with reference to FIGS. 11A-11E are repeated for arrays of chip-size photovoltaic cells 454₁ and 454₃. It is further noted that the method detailed herein above can be performed for any number of arrays of chip-size photovoltaic cells (e.g., six arrays).

Reference is now made to FIGS. 12A, 12B and 12C. FIG. 12A is a bottom view schematic illustration of a multi-head vacuum jig, generally reference 500, constructed and operative in accordance with a further embodiment of the disclosed technique. FIG. 12B is a top view schematic illustration of the multi-head vacuum jig of FIG. 12A. FIG. 12C is a rear view schematic illustration of the multi-head vacuum jig of FIG. 12A.

Multi-head vacuum jig 500 includes a plurality of vacuum head 502 and a vacuum source coupler 504. Each of vacuum heads 502 is positioned according to the respective position of each photovoltaic cell of an array of chip-size photovoltaic cells (not shown—e.g., array 354₂ of FIGS. 11A-11E). Each of vacuum heads 502 picks up and transfers a chip-size photovoltaic cell by employing vacuum supplied through vacuum source coupler 504 by a vacuum source (not shown—e.g., a vacuum pump).

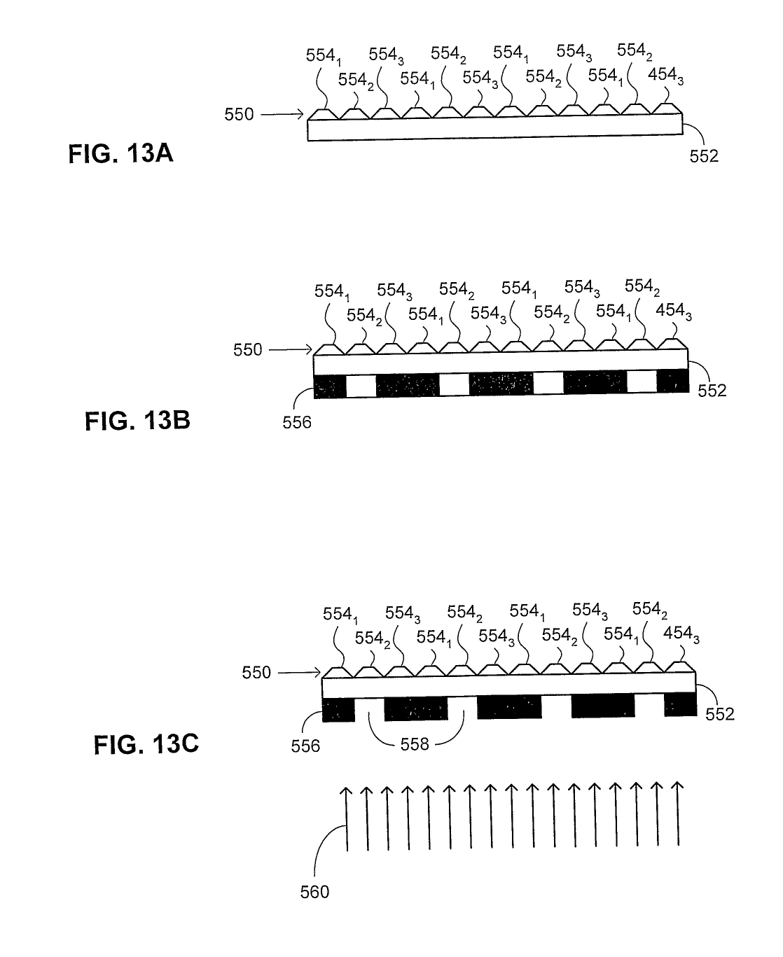

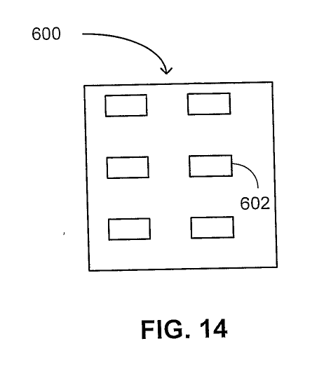

A second method for separating an array of chip-sized photovoltaic cells and transferring the array is detailed herein below with reference to FIGS. 13A, 13B, 13C and 14. Reference is now made to FIGS. 13A-13C, which are schematic illustrations of the steps for performing a second method for separating an array of chip-size photovoltaic cells, diced out of a wafer-size photovoltaic cell, and transferring the array onto a support substrate, operative in accordance with another embodiment of the disclosed technique.

With reference to FIG. 13A, a wafer-size photovoltaic cell 550 is coupled with a UV sensitive dicing tape 552 (e.g., Wafer-size photovoltaic cell 300 and dicing tape layer 304 of FIGS. 6A-6C). Wafer-size photovoltaic cell 550 is diced into three arrays of chip-size photovoltaic cells 554₁, 554₂ and 554₃ (e.g., chip-size photovoltaic cells 302 of FIGS. 6A-6C). The dimensions of each of the photovoltaic cells of the arrays of chip-size photovoltaic cells 554₁, 554₂ and 554₃, as well as the number of arrays of chip-size cells and the dimensions of the respective top contacts are determined in accordance with the disclosed technique (i.e., equations 4, 5, 6, 7 and 8).

With reference to FIG. 13B, a mask 556 is aligned to the bottom surface of wafer-size photovoltaic panel 550. Mask 556 includes a plurality of opening 558. The dimensions of each of opening 558 correspond to the dimensions of each of the photovoltaic cells of each of arrays of chip-size photovoltaic cells 554₁, 554₂ and 554₃. The position of each of openings 558 corresponds to the position of a respective photovoltaic cell of array of chip-size photovoltaic cells 554₂.

With reference to FIG. 13C, mask 556 and UV sensitive dicing tape 552 are irradiated with UV radiation 560 from bellow. The portions of UV sensitive dicing tape 552 which correspond to each of opening 558 of mask 556 are irradiated with UV radiation 560 and as a result the adhesion power thereof weakens. After irradiation of mask 556 the steps of the first method as detailed herein above with reference to FIGS. 11A-11E, are repeated for wafer-size photovoltaic panel 550.

Reference is now made to FIG. 14, which is a schematic illustration of a UV mask, generally referenced 600, constructed and operative in accordance with a further embodiment of the disclosed technique. UV mask 600 includes a plurality of opening 602. The dimensions and the position of each of openings 602 correspond to the dimension and position of each photovoltaic cell of an array of chip-size photovoltaic cells (not shown—e.g., array 554₂ of FIGS. 11A-11E).

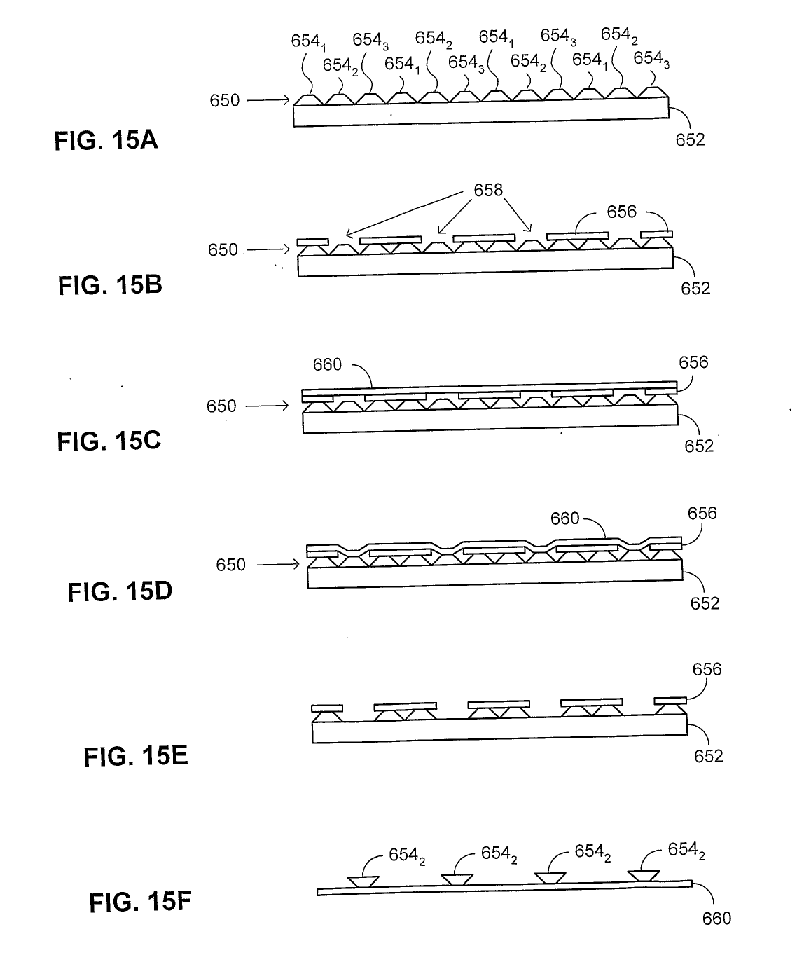

A third method for separating an array of chip-sized photovoltaic cells and transferring the array is detailed herein below with reference to FIGS. 15A-15F. Reference is now made to FIGS. 15A, 15B, 15C, 15D, 15E and 15F, which are schematic illustrations of the steps for performing a third method for separating an array of chip-size photovoltaic cells, diced out of a wafer-size photovoltaic cell, and transferring the array onto a support substrate, operative in accordance with another embodiment of the disclosed technique.

With reference to FIG. 15A, a wafer-size photovoltaic cell 650 is coupled with a non-UV sensitive dicing tape 652 (e.g., Wafer-size photovoltaic cell 300 and dicing tape layer 304 of FIGS. 6A-6C). Wafer-size photovoltaic panel 650 is diced into three arrays of chip-size photovoltaic cells 654₁, 654₂ and 654₃ (e.g., chip-size photovoltaic cells 302 of FIGS. 6A-6C). The dimensions of each of the photovoltaic cells of the pluralities of chip-size photovoltaic cells 654₁, 654₂ and 654₃, as well as the number of arrays of chip-size cells and the dimensions of the respective top contacts are determined in accordance with the disclosed technique (i.e., equations 4, 5, 6, 7 and 8).

With reference to FIG. 15B, a non-stick mask 656 is aligned to the top surface of wafer-size photovoltaic panel 650. Non-stick mask 556 includes a plurality of opening 658. The dimensions of each of opening 658 correspond to the dimensions of each of the photovoltaic cells of each of arrays of chip-size photovoltaic cells 654₁, 654₂ and 654₃. The position of each of openings 658 corresponds to the position of a respective photovoltaic cell of array of chip-size photovoltaic cells 654₂.

With reference to FIG. 15C, an adhesive tape substrate 660 is aligned over the top surface of non-stick mask 556. Adhesive tape substrate 660 is either UV sensitive or non UV sensitive. With reference to FIG. 15D, adhesive tape substrate 660 is pressed against non-stick mask 656 and photovoltaic wafer 650, such that adhesive tape substrate 660 adheres to array of chip-sized photovoltaic cells 654₂ through openings 658 of non-stick mask 660.

With reference to FIG. 15E, adhesive tape substrate 660 is picked up, along with array of chip-sized photovoltaic cells 654₂. Arrays of chip-sized photovoltaic cells 654₁ and 654₃ remain on non-UV sensitive dicing tape 652. Non-stick mask 656 is removed from photovoltaic wafer 650 (i.e., removed from arrays of chip-sized photovoltaic cells 654₁ and 654₃). With reference to FIG. 15F, adhesive tape substrate 660 transfers array of chip-sized photovoltaic cells 654₂. The steps of FIGS. 15A-15F are repeated for each of the arrays of photovoltaic wafer 650 (e.g., arrays 654₁ and 654₃). It is noted that the method detailed herein above is performed for any number of arrays of chip-sized photovoltaic cells, as determined and diced in accordance with the disclosed technique. It is further noted that the shape of non stick mask 656 is substantially similar to that of UV mask 600 of FIG. 14.

A fourth method for separating an array of chip-sized photovoltaic cells and transferring the array includes the first three steps of the second method followed by the steps of the third method. In other words the fourth method includes the steps detailed herein above with reference to FIGS. 13A-13C, followed by 15A-15F.

It will be appreciated by persons skilled in the art that the disclosed technique is not limited to what has been particularly shown and described hereinabove. Rather the scope of the disclosed technique is defined only by the claims, which follow.

1. Method for determining the dimensions of a plurality of chip-size photovoltaic cells diced out of a photovoltaic wafer, the method comprising the following procedures:
determining the field of view angle of a plurality of crossed compound parabolic concentrators of an optical layer;
determining the index of refraction of the material forming said optical layer;
determining the dimensions of the optical entry aperture and the optical exit aperture of said crossed compound parabolic concentrators, as well as the distance separating the optical entry apertures of adjacent ones of said crossed compound parabolic concentrators;
determining a dicing width for dicing said photovoltaic wafer into said plurality of chip-size photovoltaic cells; and
determining the dimensions of said plurality of chip-size photovoltaic cells according to the dimensions of the optical entry aperture of said plurality of crossed compound parabolic concentrators, the distance separating the optical entry apertures of adjacent ones of said crossed compound parabolic concentrators, the index of refraction of said optical layer, the field of view angle of said plurality of crossed compound parabolic concentrators and according to said dicing width.

2. The method according to claim 1, wherein said procedure of determining the dimensions of said plurality of chip-size photovoltaic cells is performed according to the following statements:
C_{X}=[(Lc_{X}+D_{X})/Int(n/sin(α_{X}/2))]−D_{W}
C_{Y}=[(Lc_{Y}+D_{Y})/Int(n/sin(α_{Y}/2))]−D_{W}.

3. The method according to claim 1, wherein said procedure of determining said dicing width is performed such that the dimensions of said plurality of chip-size photovoltaic cells are larger than the dimensions of the optical exit aperture of said crossed compound parabolic concentrators for said plurality of chip-size photovoltaic cells which include a top contact.

4. The method according to claim 1, wherein said procedure of determining said dicing width is performed such that the dimensions of said plurality of chip-size photovoltaic cells are at least equal to the dimensions of the optical exit aperture of said crossed compound parabolic concentrators for said plurality of chip-size photovoltaic cells which do not include a top contact.

5. The method according to claim 1, further comprising the procedure of determining the number of arrays, which said plurality of chip-size photovoltaic cells are arranged in, according to the index of refraction of said optical layer and the field of view angle of said plurality of crossed compound parabolic concentrators.

6. The method according to claim 5, wherein said procedure of determining the number of arrays, which said plurality of chip-size photovoltaic cells are arranged in, is performed according to the following statement:
Int(n/sin(α_{X}/2))*Int(n/sin(α_{Y}/2)).

7. The method according to claim 1, further comprising the procedure of determining the dimensions of a top contact for each of said plurality of chip-size photovoltaic cells according to the dimensions of said plurality of chip-size photovoltaic cells and according to the dimensions of the optical exit aperture of said crossed compound parabolic concentrators.

8. The method according to claim 7, wherein said procedure of determining the dimensions of a top contact for each of said plurality of chip-size photovoltaic cells is performed according to the following statements:
Tc_{X}=(C_{X}−Lo_{X})/2
Tc_{Y}=(C_{Y}−Lo_{Y})/2.

9. The method according to claim 1, further comprising the procedure of determining the distances between adjacent ones of a plurality of passivation islands according to the dimensions of said plurality of chip-size photovoltaic cells, the dimensions of the optical exit apertures of said crossed compound parabolic concentrators and according to said dicing width, said plurality of passivation islands corresponding to the dimensions of said plurality of chip-size photovoltaic cells.

10. The method according to claim 9, wherein said procedure of determining the distances between adjacent ones of said plurality of passivation islands is performed according to the following statements:
P_{X}=C_{X}−Lo_{X}+D_{W}
P_{Y}=C_{Y}−Lo_{Y}+D_{W}.

11. Method for separating an array of chip-sized photovoltaic cells out of a photovoltaic wafer, and transferring the array onto a support substrate, the method comprising the following procedures:
coupling said photovoltaic wafer with a dicing tape;
dicing said photovoltaic wafer for producing at least said array of chip-sized photovoltaic cells;
positioning a multi-head vacuum jig above said photovoltaic wafer such that each of a plurality of vacuum heads of said vacuum jig being positioned above each of said cells of said array of chip-sized photovoltaic cells; and
transferring said array of chip-sized photovoltaic cells onto said support substrate.

12. The method according to claim 11, wherein said dicing tape is a non-UV sensitive dicing tape.

13. The method according to claim 11, wherein said dicing tape is a UV sensitive dicing tape.

14. The method according to claim 13, further comprising the following sub procedures before the procedure of positioning said multi-dead vacuum jig:
aligning a UV mask including a plurality of openings, the dimensions and position of each of said opening corresponds to a respective cell of said array of chip-sized photovoltaic cells, to the bottom surface of said UV sensitive dicing tape, such that each of said openings is aligned with said respective cell of said array of chip-sized photovoltaic cells;
irradiating with UV radiation said UV mask and said UV sensitive dicing tape such that said UV dicing tape loses at least a portion of its adhesive power at the positions of each of said cells of said array of chip-sized photovoltaic cells.

15. Method for separating an array of chip-sized photovoltaic cells out of a photovoltaic wafer, and transferring the array onto a support substrate, the method comprising the procedures of:
dicing said photovoltaic wafer for producing at least said array of chip-sized photovoltaic cells;
aligning a nonstick mask to the top surface of said photovoltaic wafer, said non stick mask including a plurality of openings, each of said openings corresponds in dimensions and position to a respective cell of said array of chip-sized photovoltaic cells;
aligning an adhesive tape substrate to the top surface of said non stick mask and said photovoltaic wafer;
pressing said adhesive tape substrate against said non-stick mask and against said photovoltaic wafer, such that said adhesive tape substrate adheres to said array of chip-sized photovoltaic cells through said openings of said non-stick mask; and
transferring said array of chip-sized photovoltaic cells onto said support substrate.
